(19) United States
(12) Patent Application Publication
(10) Pub. No.: US 2014/0077285 A1
(43) Pub. Date: Mar. 20, 2014

(54) NON-VOLATILE SEMICONDUCTOR MEMORY DEVICE AND METHOD FOR MANUFACTURING NON-VOLATILE SEMICONDUCTOR MEMORY DEVICE

(71) Applicant: KABUSHIKI KAISHA TOSHIBA, Tokyo (JP)

(72) Inventors: Homuro NODA, Mie (JP); Takuji KUNIYA, Mie (JP)

(73) Assignee: KABUSHIKI KAISHA TOSHIBA, Tokyo (JP)

(21) Appl. No.: 13/845,812

(22) Filed: Mar. 18, 2013

Related U.S. Application Data
(60) Provisional application No. 61/702,970, filed on Sep. 19, 2012.

(51) Int. Cl. H01L 29/792; H01L 29/66

(52) U.S. Cl. CPC H01L 29/7926; H01L 29/66833
USPC 257/324; 438/269

(57) ABSTRACT

An embodiment includes: a stacked body having an impurity doped silicon layer and an interlayer insulating film alternately stacked on each other in which one layer of the impurity doped silicon layers is replaced with a conductive film enabling forming a metal oxide; a hole penetrating the stacked body in a stacking direction; a channel layer formed in the hole along the stacking direction of the stacked body; a tunnel insulating film formed between an inner surface of the hole and the channel layer; a charge trapping layer formed between the inner surface of the hole and the tunnel insulating film; and a block insulating film formed between the inner surface of the hole and the charge trapping layer.

### CROSS-REFERENCE TO RELATED APPLICATIONS

This application is based upon and claims the benefit of priority from Provisional Patent Application No. 61/702970, filed on Sep. 19, 2012; the entire contents of which are incorporated herein by reference.

### FIELD

Embodiments generally relate to a non-volatile semiconductor memory device and a method for manufacturing a non-volatile semiconductor memory device.

### BACKGROUND

In order to aim to highly integrate a non-volatile semiconductor memory device, memory cells are sometimes three-dimensionally disposed on each other.

### BRIEF DESCRIPTION OF THE DRAWINGS

FIG. 1 is a perspective view of an exemplary overall configuration of a memory cell array of a non-volatile semiconductor memory device according to a first embodiment;

FIG. 2 is a cross sectional view of an enlarged portion E in FIG. 1;

FIG. 3 is a perspective view of an exemplary circuit configuration of the memory cell array in FIG. 1;

FIG. 4 is a perspective view of an exemplary circuit configuration of a block in FIG. 3;

FIGS. 5A to 5E are cross sectional views of a method for manufacturing a memory cell array of a non-volatile semiconductor memory device according to a second embodiment;

FIGS. 6A to 6F are cross sectional views of a method for manufacturing a memory cell array of a non-volatile semiconductor memory device according to a third embodiment; and

FIGS. 7A to 7C are cross sectional views of the method for manufacturing the memory cell array of the non-volatile semiconductor memory device according to the third embodiment.

### DETAILED DESCRIPTION

According to an embodiment, a stacked body, a hole, a channel layer, a tunnel insulating film, a charge trapping layer, and a block insulating film are provided. The stacked body has an impurity doped silicon layer and an interlayer insulating film alternately stacked on each other, in which one layer of the impurity doped silicon layers is replaced with a conductive film that can form a metal oxide. The hole penetrates the stacked body in the stacking direction. The channel layer is formed in the hole along the stacking direction of the stacked body. The tunnel insulating film is formed between the inner surface of the hole and the channel layer. The charge trapping layer is formed between the inner surface of the hole and the tunnel insulating film. The block insulating film is formed between the inner surface of the hole and the charge trapping layer.

In the following, a non-volatile semiconductor memory device and a method for manufacturing a non-volatile semiconductor memory device according to embodiments will be described in detail with reference to the accompanying drawings. It is noted that the present invention is not limited to these embodiments.

### First Embodiment

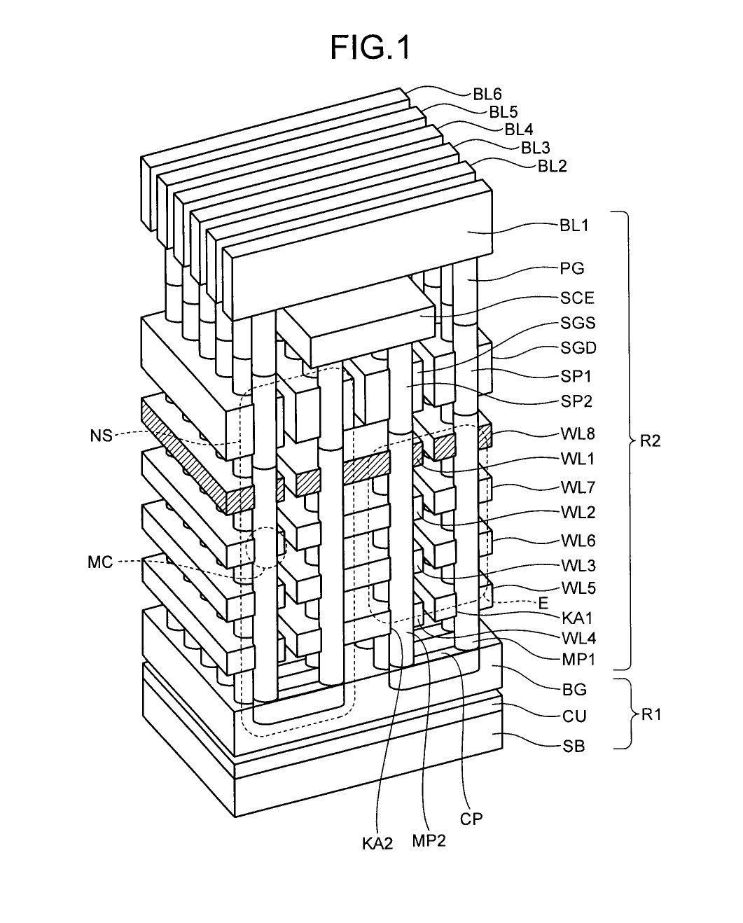

FIG. 1 is a perspective view of an exemplary overall configuration of a memory cell array of a non-volatile semiconductor memory device according to a first embodiment. It is noted that in an example in FIG. 1, a method was illustrated in which memory cells MC stacked in four layers are bent at the lower end and eight memory cells MC are connected in series to form a NAND string NS. Moreover, in the example in FIG. 1, interlayer insulating films between word lines WL1 to WL4 and between word lines WL5 to WL8 were omitted.

In FIG. 1, a circuit region R1 is provided on a semiconductor substrate SB, and a memory region R2 is provided on a circuit region R1. It is noted that a substrate on which the circuit region R1 is provided may be different from a substrate on which the memory region R2 is provided.

In the circuit region R1, a circuit layer CU is then formed on the semiconductor substrate SB. A back gate layer BG is formed on the circuit layer CU, and a connect layer CP is formed on the back gate layer BG. Pillars MP1 and MP2 are adjacently disposed on the connect layer CP, and the lower ends of the pillars MP1 and MP2 are connected to each other through the connect layer CP. Moreover, four layers of the word lines WL4 to WL1 are alternately in turn stacked on the interlayer insulating film on the connect layer CP, and four layers of the word lines WL5 to WL8 are alternately in turn stacked on the interlayer insulating film in such a way that the word lines WL5 to WL8 are provided adjacently to the word lines WL4 to WL1. Here, the word lines WL2 to WL7, which are the first layer to the third layer, can be formed of an impurity doped silicon layer. The topmost word lines WL1 and WL8 can be formed of a conductive film that can form a metal oxide. This metal oxide can use an etching residual substance for a raw material in forming holes KA1 and KA2 on the conductive films forming the word lines WL1 and WL8. The material of the conductive film may be a metal such as Ti and Al, or may be a metal compound such as TiN and AlN. A metal oxide made from the conductive film may be TiOₓ or AlₓO_{y} (x and y are positive integers). For example, in the case where the conductive film is Ti, Ti reacts with an etching gas in etching the conductive film, so that TiO can be formed. Moreover, there is described a method for forming the topmost word lines WL1 and WL8 with the conductive film that can form a metal oxide among the word lines WL1 to WL8. However, the word lines WL2 and WL7, which are the third layers, may be formed of the conductive film that can form a metal oxide, or the word lines WL3 and WL6, which are the second layers, may be formed of the conductive film that can form a metal oxide.

A select gate line SGS is stacked on the topmost word line WL1 through the interlayer insulating film, and a select gate line SGD is stacked on the topmost word line WL8 through the interlayer insulating film. It is noted that the select gate line SGD can be formed of an impurity doped silicon layer.

This stacked body is then formed with the hole KA2 that penetrates the word lines WL4 to WL1 and the select gate line SGS, and the hole KA1 that penetrates the word lines WL5 to WL8 and the select gate line SGD. The pillar MP1 penetrates the word lines WL5 to WL8 through the hole KA1, and then the memory cell MC is formed individually at the word lines WL5 to WL8, and the pillar MP2 penetrates the word lines WL1 to WL4 through the hole KA2, and then the memory cell MC is formed individually at the word lines WL1 to WL4.

Moreover, pillars SP1 and SP2 are formed on the pillars MP1 and MP2, respectively. The pillar SP1 then penetrates the select gate line SGD through the hole KA1, and the pillar SP2 penetrates the select gate line SGS through the hole KA2, so that the NAND string NS is formed.

Furthermore, a source line SCE connected to the pillar SP2 is provided on the select gate line SGS, and bit lines BL1 to BL6 connected to the pillar SP1 through a plug PG are formed on the source line SCE for individual columns. It is noted that the pillars MP1 and MP2 can be disposed at the intersection points between the bit lines BL1 to BL6 and the word lines WL1 to WL8.

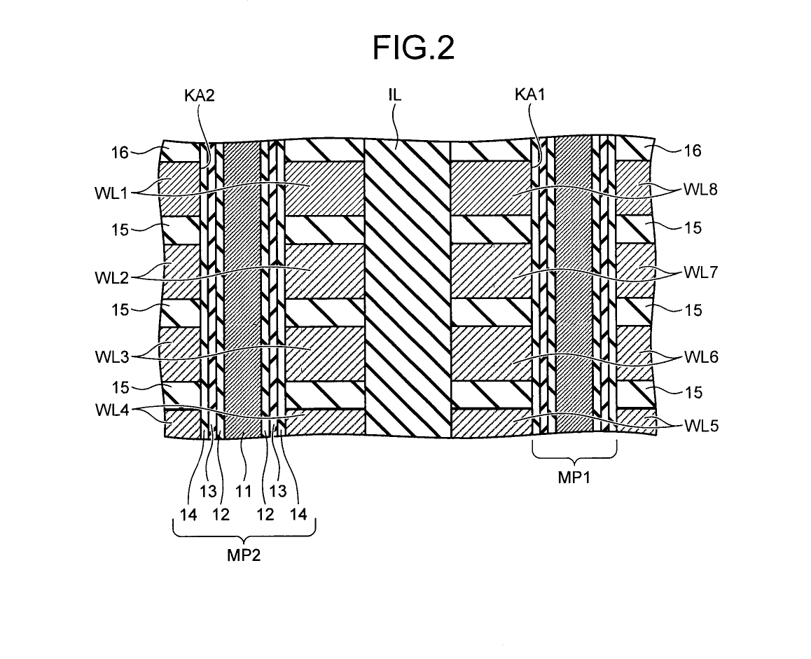

FIG. 2 is a cross sectional view of an enlarged portion E in FIG. 1.

In FIG. 2, an insulator IL is filled between the word lines WL1 to WL4 and the word lines WL5 to WL8. An interlayer insulating film 15 is formed between the word lines WL1 to WL4 and between the word lines WL5 to WL8.

Moreover, the hole KA2 that penetrates the word lines WL1 to WL4 and the interlayer insulating film 15 in the stacking direction is formed on the word lines WL1 to WL4 and the interlayer insulating film 15. The hole KA1 that penetrates the word lines WL5 to WL8 and the interlayer insulating film 15 in the stacking direction is formed on the word lines WL5 to WL8 and the interlayer insulating film 15. The pillar MP1 is formed in the hole KA1, and the pillar MP2 is formed in the hole KA2.

A pillar-shaped semiconductor 11 is formed on the centers of the pillars MP1 and MP2. A tunnel insulating film 12 is formed between the inner surfaces of the holes KA1 and KA2 and the pillar-shaped semiconductor 11. A charge trapping layer 13 is formed between the inner surfaces of the holes KA1 and KA2 and the tunnel insulating film 12. A block insulating film 14 is formed between the inner surfaces of the holes KA1 and KA2 and the charge trapping layer 13. A semiconductor such as Si can be used for the pillar-shaped semiconductor 11, for example. A silicon oxide film can be used for the tunnel insulating film 12 and the block insulating film 14, for example. For the charge trapping layer 13, a silicon nitride film or an ONO film (a three-layer structure of a silicon oxide film/a silicon nitride film/a silicon oxide film) can be used, for example.

Here, the word lines WL1 and WL8 are formed of the conductive film that can form a metal oxide in the stacked body in which the word lines WL1 to WL4 and the interlayer insulating film 15 are alternately stacked on each other and the word lines WL5 to WL8 and the interlayer insulating film 15 are alternately stacked on each other, so that a protective film made of a metal oxide can be formed on the side walls of mask patterns corresponding to the holes KA1 and KA2 in forming the holes KA1 and KA2 on the word lines WL1 and WL8. Therefore, a reduction in the film of the mask patterns corresponding to the holes KA1 and KA2 can be suppressed, and the remaining thickness of the mask pattern can be secured.

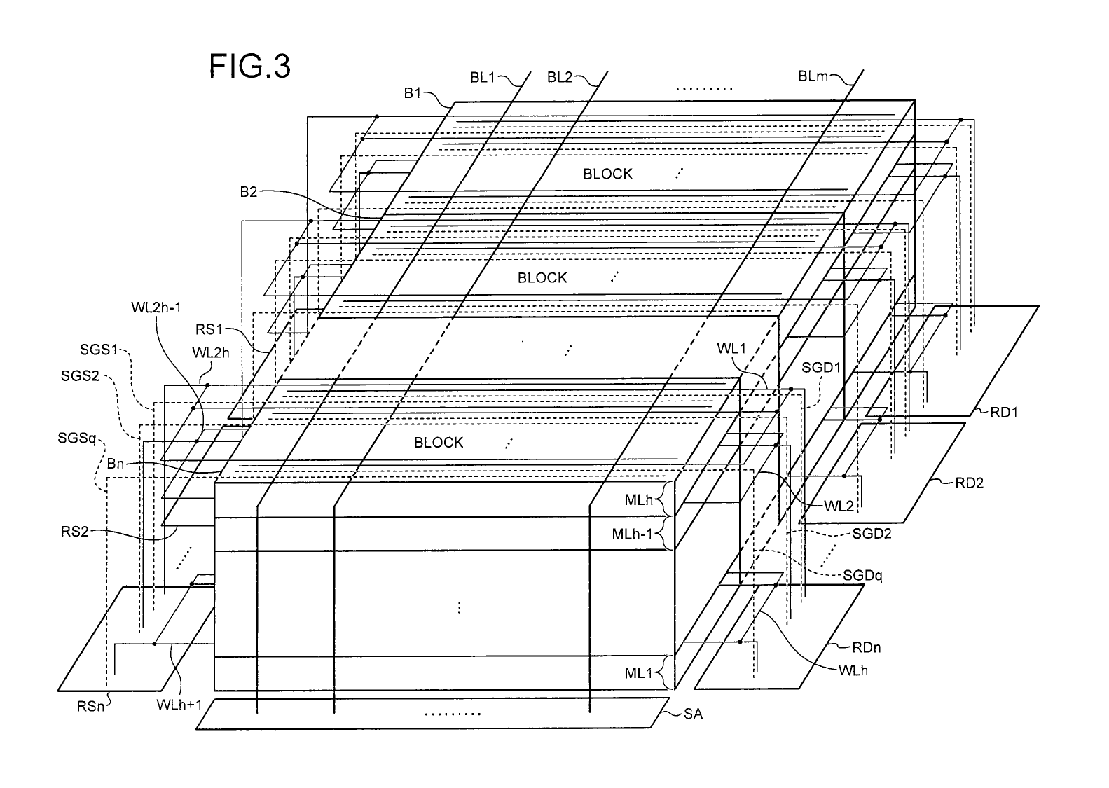

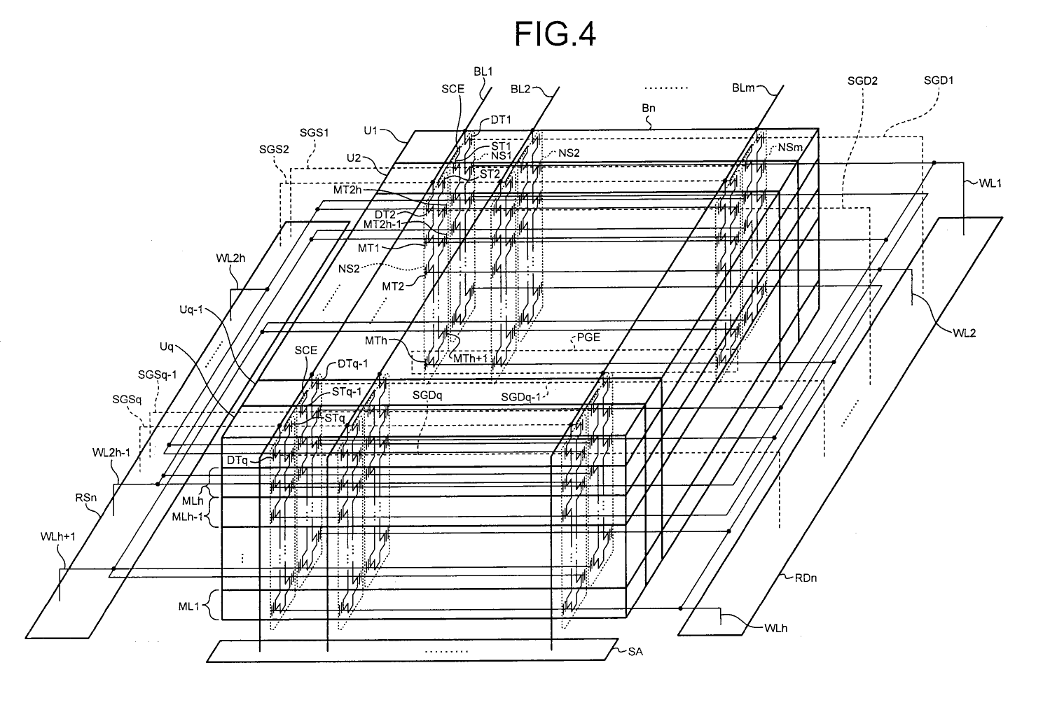

FIG. 3 is a perspective view of an exemplary circuit configuration of the memory cell array in FIG. 1, and FIG. 4 is a perspective view of an exemplary circuit configuration of a block in FIG. 3. It is noted that in the example in FIGS. 3 and 4, a three-dimensional NAND flash memory will be described in which memory cells are three-dimensionally disposed. Moreover, in the example in FIGS. 3 and 4, a method is illustrated in which word lines WL1 to WLh and select gate lines SGD1 to SGDq (on the drain side) and word lines WLh+1 to WL2h and select gate lines SGS1 to SGSq (on the source side) are lead in the directions opposite to each other.

In FIGS. 3 and 4, this memory cell array has a layer structure from a block to a string unit to a NAND string to a memory cell.

The memory cell array is disposed with n blocks of blocks B1 to Bn in the column direction (n is an integer of two or more). The blocks B1 to Bn include h layers of cell layers ML1 to MLh that are stacked through an interlayer insulating film (h is a positive integer). Moreover, the blocks B1 to Bn include q units of string units U1 to Uq that are disposed in parallel with each other in a Y-direction (q is a positive integer). The string units U1 to Uq include m strings of NAND strings NS1 to NSm that are disposed in parallel with each other in the row direction (m is a positive integer). The NAND strings NS1 to NSm include 2h cell transistors of cell transistors MT1 to MT2h (h is a positive integer) and select transistors ST1 to STq and DT1 to DTq disposed at both ends of 2h of the cell transistors for the individual string units U1 to Uq. Furthermore, the cell transistors MT1 to MT2h are in turn connected to each other in series. The cell transistors MT1 to MT2h are then disposed in ascending order from the bit line BL side to the source line SCE side. It is noted that a back gate transistor may be provided between h cell transistors MT1 to MTh and h cell transistor MTh+1 to MT2h. A back gate line BG can be connected to the gate of the back gate transistor. In the connection, the NAND strings NS1 to NSm are bent between the cell transistors MTh and MTh+1 in the column direction through the back gate transistor.

Moreover, the blocks B1 to Bn are provided with the word lines WL1 to WL2h and the select gate lines SGD1 to SGDq and SGS1 to SGSq in parallel in the column direction, and bit lines BL1 to BLm in parallel in the row direction.

Here, the word lines WL1 to WL2h and the select gate lines SGD1 to SGDq and SGS1 to SGSq are provided separately for the individual blocks B1 to Bn. The bit lines BL1 to BLm are shared between the blocks B1 to Bn.

Row decoders RD1 to RDn and RS1 to RSn are then provided for the individual blocks B1 to Bn. For example, in the block Bn, the word lines WL1 to WLh and the select gate lines SGD1 to SGDq are then lead in the direction opposite to the word lines WLh+1 to WL2h and the select gate lines SGS1 to SGSq. The row decoder RDn is then disposed in the leading direction of the word lines WL1 to WLh and the select gate lines SGD1 to SGDq. The row decoder RSn is disposed in the leading direction of the word lines WLh+1 to WL2h and the select gate lines SGS1 to SGSq.

Furthermore, a sense amplifier circuit SA is shared between the blocks B1 to Bn. The bit lines BL1 to BLm are then connected to the sense amplifier circuit SA.

In addition, in the blocks B1 to Bn, the select gate lines SGD1 to SGDq and SGS1 to SGSq are individually provided for the string units U1 to Uq.

In the blocks B1 to Bn, the word lines WL1 to WLh are connected in common to the gates of the corresponding cell transistors MT1 to MTh among the different string units U1 to Uq. Namely, the word line WL1 is connected in common to all the gates of the cell transistors MT1 of the string units U1 to Uq in the block B1, for example. For example, the word line WL2 is connected in common to all the gates of the cell transistors MT2 of the string units U1 to Uq in the block B1. The word lines WL3 to WLh are connected in common to the gates of the corresponding cell transistors MT3 to MTh similarly to the word lines WL1 and WL2.

In the blocks B1 to Bn, the word lines WLh+1 to WL2h are connected in common to the gates of the corresponding cell transistors MTh+1 to MT2h among the different string units U1 to Uq.

In the blocks B1 to Bn, the word lines WLh+1 to WL2h are connected in common to the gates of the corresponding cell transistors MT1 to MTh of the different string units U1 to Uq. Therefore, it is possible to reduce the lead lines from the word lines WL1 to WL2h by 1/q lines, and it is possible to suppress an increase in the scale of the row decoders RD1 to RDn and RS1 to RSn as compared with the case where the word line WL is lead to the individual string units U1 to Uq.

Moreover, the word lines WL1 to WL2h are separated between the individual blocks B1 to Bn, so that it is possible to suppress an increase in a load applied in driving the word lines WL1 to WL2h even in the case where the word lines WL1 to WL2h are shared between a plurality of different string units in the same blocks B1 to Bn.

Furthermore, the select transistors DT1 to DTq and ST1 to STq that select the string units U1 to Uq are provided in the string units U1 to Uq. The cell transistors MT1 of the NAND strings NS1 to NSq are then connected to the bit lines BL1 to BLm through the individual select transistors DT1 to DTq. In addition, the cell transistors MT2h of the NAND strings NS1 to NSq are connected to the source line SCE through the individual select transistors DT1 to DTq.

Moreover, the select gate lines SGD1 to SGDq are connected to the gates of the select transistors DT1 to DTq, and the select gate lines SGS1 to SGSq are connected to the gates of the select transistors ST1 to STq.

Furthermore, among the cell transistors that share the word line WL, a plurality of cell transistors in the common string units U1 to Uq forms a page PGE. This page PGE is a unit to write data to the memory cell and a unit to read data from the memory cell.

### Second Embodiment

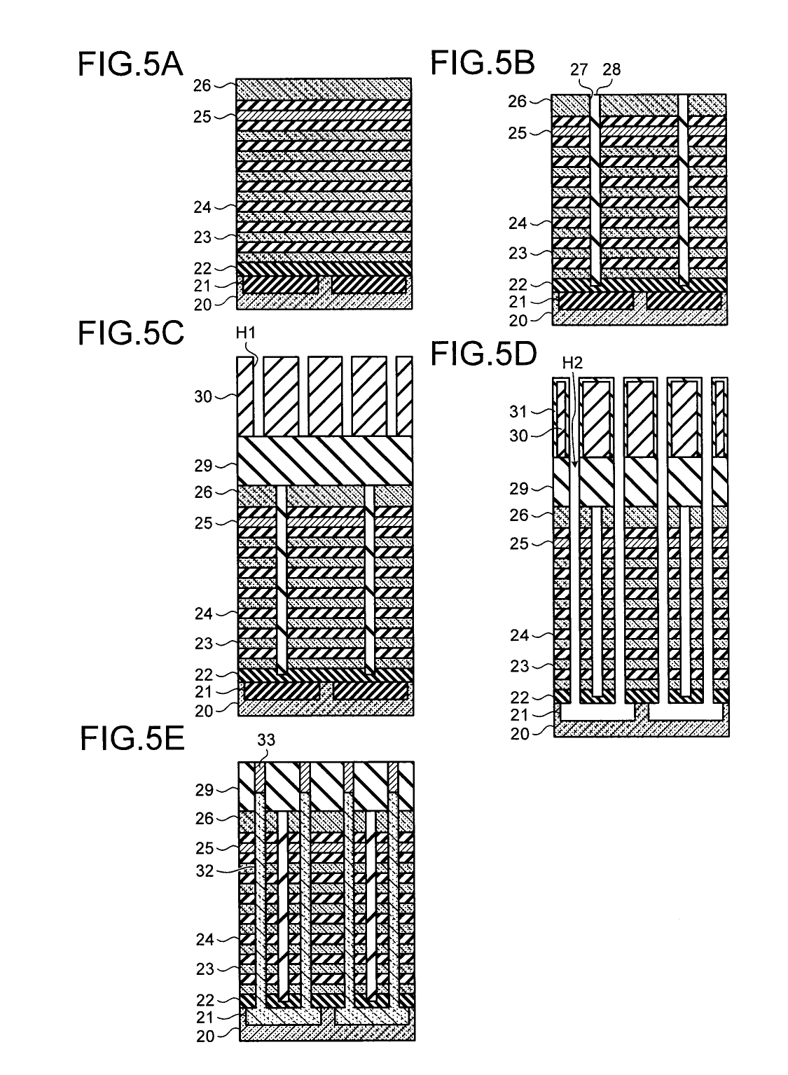

FIGS. 5A to 5E are cross sectional views of a method for manufacturing a memory cell array of a non-volatile semiconductor memory device according to a second embodiment. It is noted that in the second embodiment, the case was taken as an example where the memory cells MC in FIG. 1 are stacked in eight layers.

In FIG. 5A, a connecting portion 21 is provided in a base layer 20. After filling a sacrificial film in the connecting portion 21, an interlayer insulating film 22 is then formed on the base layer 20. It is noted that a semiconductor substrate can be used for the base layer 20, for example. A silicon oxide film can be used for the material of the interlayer insulating film 22, for example. A material of a selection ratio smaller than that of the interlayer insulating film 22 can be used for the sacrificial film filled in the connecting portion 21.

An impurity doped silicon layer 23 and an interlayer insulating layer 24 are then alternately stacked on each other by a method such as CVD. It is noted that the interlayer insulating layer 24 may be a BSG (Boron Silicate Glass) film or may be a silicon oxide film, for example. However, preferably, the material of the insulating layer 24 is selected in such a way that the etching rate of the insulating layer 24 is equal to the etching rate of the impurity doped silicon layer 23 as much as possible. Moreover, B, P, or As can be used for the impurity of the impurity doped silicon layer 23, for example.

Here, in the stacked body formed of the impurity doped silicon layers 23 and the interlayer insulating layers 24, a conductive film 25 is formed instead of the topmost impurity doped silicon layer 23 by a method such as CVD and sputtering. It is noted that the material of the conductive film 25 can be selected so as to form a metal oxide. For example, the material of the conductive film 25 may be a metal such as Ti and Al, or may be a metal compound such as TiN and AlN. An impurity doped silicon layer 26 is then formed on the conductive film 25 through the interlayer insulating layer 24 by a method such as CVD.

Subsequently, as illustrated in FIG. 5B, the impurity doped silicon layers 26 and 23, the interlayer insulating films 24 and 22, and the conductive film 25 are patterned, and a slit 27 is formed in the impurity doped silicon layers 26 and 23, the interlayer insulating films 24 and 22, and the conductive film 25 to separate the impurity doped silicon layers 26 and 23, the interlayer insulating films 24 and 22, and the conductive film 25 in the column direction. An insulator 28 is then filled in the slit 27. It is noted that a silicon oxide film can be used for the material of the insulator 28, for example.

Subsequently, as illustrated in FIG. 5C, an interlayer insulating film 29 is formed on the impurity doped silicon layer 26 by a method such as CVD. A mask pattern 30 provided with an opening H1 is then formed on the interlayer insulating film 29. It is noted that the material of the mask pattern 30 may be a BSG film or may be a TEOS (tetraethoxysilane: Si(OC₂H₅)₄) film.

Subsequently, as illustrated in FIG. 5D, the impurity doped silicon layers 26 and 23, the interlayer insulating films 29, 24, and 22, and the conductive film 25 are etched through the mask pattern 30 to form a hole H2 in the impurity doped silicon layers 26 and 23, the interlayer insulating films 29, 24, and 22, and the conductive film 25. Here, when etching the conductive film 25, a protective film 31 made of a metal oxide is formed on the side wall of the opening H1 using the etching residual substance of the conductive film 25 for a raw material. Therefore, a reduction in the film of the mask pattern 30 can be suppressed, and the remaining thickness of the mask pattern 30 can be secured in forming the hole H2 in the impurity doped silicon layers 26 and 23, the interlayer insulating films 29, 24, and 22, and the conductive film 25. It is noted that a metal oxide forming the protective film 31 can be formed by causing the conductive film 25 to react with an etching gas.

Moreover, in the stacked body formed of the impurity doped silicon layers 23 and the interlayer insulating layers 24, one layer of the impurity doped silicon layers 23 is replaced with the conductive film 25, so that the penetration property of the hole H2 can be secured.

Subsequently, the sacrificial film of the connecting portion 21 is etched through the hole H2, and the sacrificial film of the connecting portion 21 is removed.

Subsequently, as illustrated in FIG. 5E, a pillar 32 is filled in the hole H2 and the connecting portion 21 by a method such as CVD. Furthermore, a part of the pillar 32 filled in the interlayer insulating film 29 is removed, and a plug 33 is filled in the removed portion. It is noted that the configuration similar to the pillar MP2 in FIG. 2 can be used for the pillar 32.

For a method for forming the pillar 32, a block insulating film 14 is formed on the inner surface of the hole H2 by a method such as CVD. Subsequently, a charge trapping layer 13 is formed on the surface of the block insulating film 14 in the hole H2 by a method such as CVD. Subsequently, a tunnel insulating film 12 is formed on the surface of the charge trapping layer 13 in the hole H2 by a method such as CVD. Subsequently, a pillar-shaped semiconductor 11 is filled in the hole H2 through the tunnel insulating film 12 by a method such as CVD. Here, a channel layer can be formed on the pillar-shaped semiconductor 11. It is noted that such a configuration may be possible in which a semiconductor layer is formed on the surface of the tunnel insulating film 12 and then a pillar-shaped insulator is filled in the hole H2, instead of filling the pillar-shaped semiconductor 11 in the hole H2.

### Third Embodiment

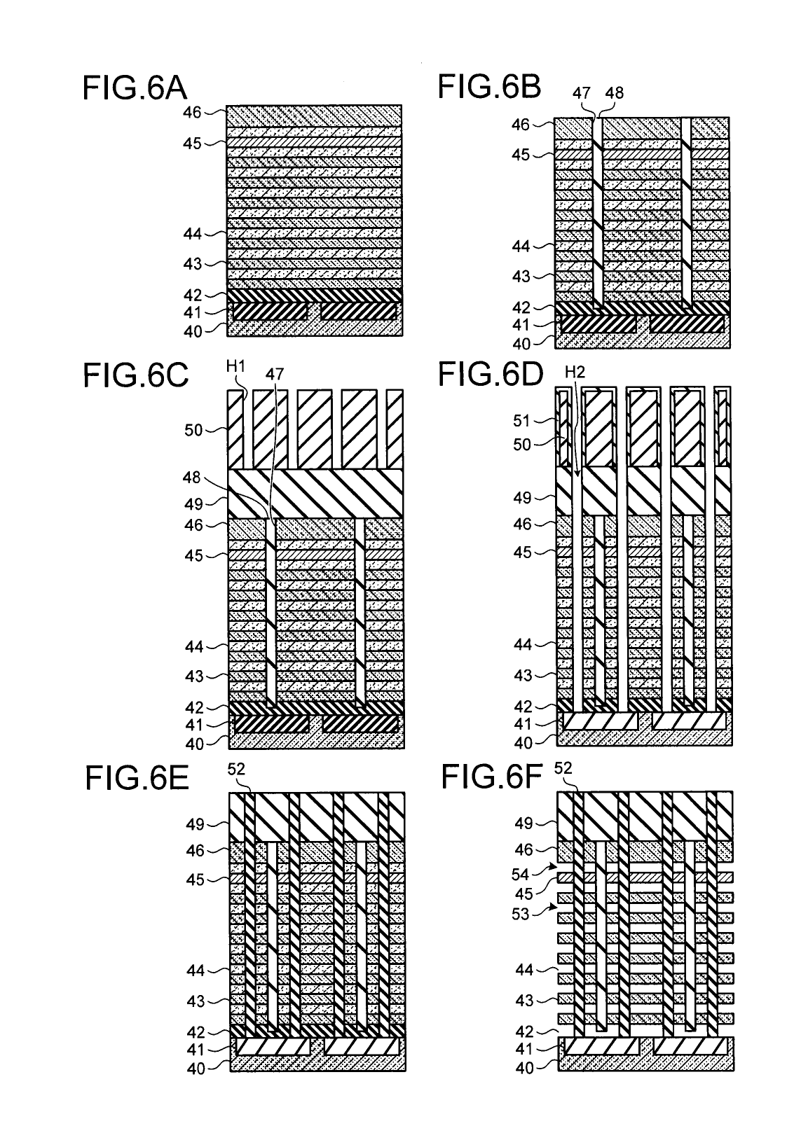

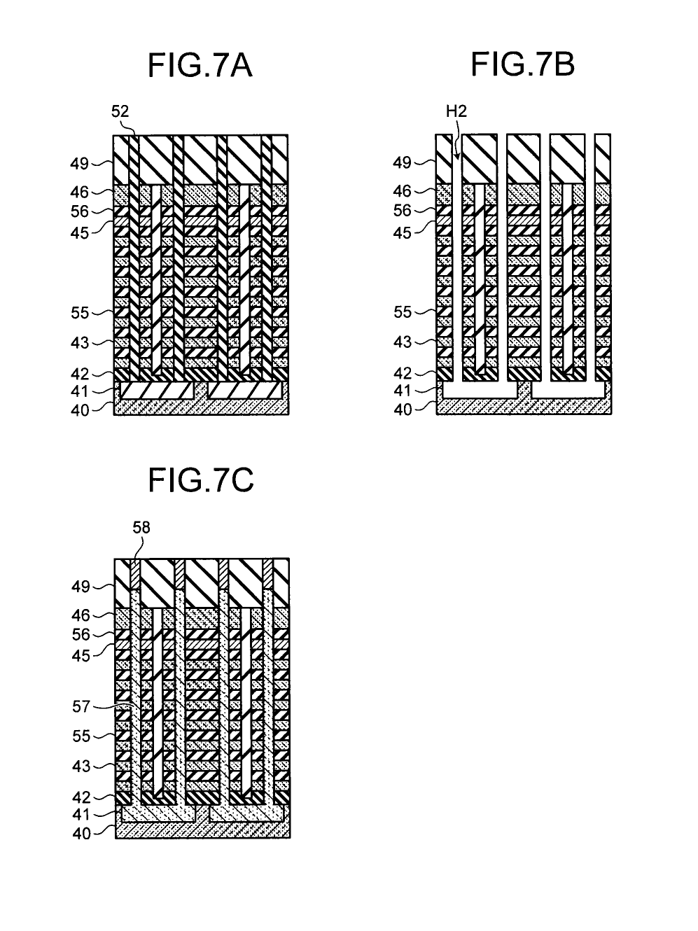

FIGS. 6A to 6F and FIGS. 7A to 7C are cross sectional views of a method for manufacturing a memory cell array of a non-volatile semiconductor memory device according to a third embodiment. It is noted that in the third embodiment, the case was taken as an example where the memory cells MC in FIG. 1 are stacked in eight layers.

In FIG. 6A, a connecting portion 41 is provided on a base layer 40. After filling a sacrificial film in the connecting portion 41, an interlayer insulating film 42 is then formed on the base layer 40. It is noted that a semiconductor substrate can be used for the base layer 40, for example. A silicon oxide film can be used for the material of the interlayer insulating film 42, for example. A material of a selection ratio smaller than that of the interlayer insulating film 42 can be used for the sacrificial film filled in the connecting portion 41.

An impurity doped silicon layer 43 and an impurity non-doped silicon layer 44 are then alternately stacked on each other by a method such as CVD. Here, in the stacked body formed of the impurity doped silicon layers 43 and the impurity non-doped silicon layers 44, a conductive film 45 is formed by a method such as CVD and sputtering, instead of the topmost impurity doped silicon layer 43. It is noted that the material of the conductive film 45 can be selected so as to form a metal oxide. For example, the material of the conductive film 45 may be a metal such as Ti and Al, or may be a metal compound such as TiN and AlN. An impurity doped silicon layer 46 is then formed on the conductive film 45 by a method such as CVD.

Subsequently, as illustrated in FIG. 6B, the impurity doped silicon layers 43 and 46, the impurity non-doped silicon layers 44, and the conductive film 45 are patterned, and a slit 47 is formed in the impurity doped silicon layers 43 and 46, the impurity non-doped silicon layers 44, and the conductive film 45 to separate the impurity doped silicon layers 43 and 46, the impurity non-doped silicon layers 44, and the conductive film 45 in the column direction. An insulator 48 is then filled in the slit 47. It is noted that a silicon oxide film can be used for the material of the insulator 48, for example.

Subsequently, as illustrated in FIG. 6C, an interlayer insulating film 49 is formed on the impurity doped silicon layer 46 by a method such as CVD. A mask pattern 50 provided with an opening H1 is then formed on the interlayer insulating film 49. It is noted that the material of the mask pattern 50 may be a BSG film or may be a TEOS (tetraethoxysilane: Si(OC₂H₅)₄) film.

Subsequently, as illustrated in FIG. 6D, the impurity doped silicon layers 43 and 46, the impurity non-doped silicon layers 44, the interlayer insulating film 42, and the conductive film 45 are etched through the mask pattern 50 to form a hole H2 in the impurity doped silicon layers 43 and 46, the impurity non-doped silicon layers 44, the interlayer insulating film 42, and the conductive film 45. Here, when etching the conductive film 45, a protective film 51 made of a metal oxide is formed on the side wall of the opening H2 using the etching residual substance of the conductive film 45 for a raw material. Therefore, a reduction in the film of the mask pattern 50 can be suppressed, and the remaining thickness of the mask pattern 50 can be secured, in forming the hole H2 in the impurity doped silicon layers 43 and 46, the impurity non-doped silicon layers 44, the interlayer insulating film 42, and the conductive film 45. Moreover, in the stacked body formed of the impurity doped silicon layers 43 and the impurity non-doped silicon layers 44, one layer of the impurity doped silicon layers 43 is replaced with the conductive film 45, so that the penetration property of the hole H2 can be secured.

Subsequently, as illustrated in FIG. 6E, a sacrificial film 52 is filled in the hole H2 by a method such as CVD, the sacrificial film 52 is planarized by a method such as CMP, and then the mask pattern 50 is removed. It is noted that a silicon oxide film or a silicon nitride film can be used for the material of the sacrificial film 52.

Subsequently, as illustrated in FIG. 6F, the impurity non-doped silicon layers 44 are selectively etched by a method such as wet etching, so that the impurity non-doped silicon layers 44 are removed, a gap 53 is formed between the impurity doped silicon layers 43, and a gap 54 is formed above and below the conductive film 45. It is noted that such a configuration may be possible in order to reduce the resistances of the impurity doped silicon layers 43 and 46 in which the impurity non-doped silicon layers 44 are removed and then the impurity doped silicon layers 43 and 46 are made to be silicide.

Subsequently, as illustrated in FIG. 7A, interlayer insulating films 55 and 56 are filled in the gaps 53 and 54 by a method such as ALD-CVD.

Subsequently, as illustrated in FIG. 7B, the sacrificial film 52 in the hole H2 is removed, and the side walls of the impurity doped silicon layers 43 and 46 and the conductive film 45 are exposed. Moreover, the sacrificial film of the connecting portion 41 is etched through the hole H2 to remove the sacrificial film of the connecting portion 41.

Subsequently, as illustrated in FIG. 7C, a pillar 57 is filled in the hole H2 and the connecting portion 41 by a method such as CVD. Furthermore, a part of the pillar 57 filled in the interlayer insulating film 49 is removed, and a plug 58 is filled in the removed portion. It is noted that the configuration similar to the pillar MP2 in FIG. 2 can be used for the pillar 57.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A non-volatile semiconductor memory device comprising:
a stacked body having an impurity doped silicon layer and an interlayer insulating film alternately stacked on each other in which one layer of the impurity doped silicon layers is replaced with a conductive film enabling forming a metal oxide;
a hole penetrating the stacked body in a stacking direction;
a channel layer formed in the hole along the stacking direction of the stacked body;
a tunnel insulating film formed between an inner surface of the hole and the channel layer;
a charge trapping layer formed between the inner surface of the hole and the tunnel insulating film; and
a block insulating film formed between the inner surface of the hole and the charge trapping layer.

2. The non-volatile semiconductor memory device according to claim 1, wherein the conductive film is replaced with a topmost impurity doped silicon layer of the stacked body.

3. The non-volatile semiconductor memory device according to claim 1, wherein the conductive film is a metal or a metal compound.

4. The non-volatile semiconductor memory device according to claim 1, wherein the conductive film is selected from Ti, TiN, Al, and AlN.

5. The non-volatile semiconductor memory device according to claim 1, wherein the metal oxide is TiOₓ or AlₓO_{y} (x and y are positive integers).

6. The non-volatile semiconductor memory device according to claim 1, wherein:
a plurality of memory cells is three-dimensionally disposed on the stacked body;
cell transistors included in the memory cell are connected in series in a height direction to form a NAND string;
two rows of the NAND strings in a same row form a string unit; and
a plurality of string units arranged in a column direction forms a block.

7. The non-volatile semiconductor memory device according to claim 6, comprising:
a bit line that selects the NAND string in the column direction;
a word line shared for individual cell layers between NAND strings in different rows sharing a same bit line; and
a select transistor provided on the individual NAND strings to select the NAND string in a row direction.

8. The non-volatile semiconductor memory device according to claim 7, wherein:
a memory cell array is formed of a plurality of blocks arranged in the column direction;
the bit line is shared between the blocks; and
the word line is separated between the blocks.

9. A method for manufacturing a non-volatile semiconductor memory device comprising the steps of:
forming a stacked body having an impurity doped silicon layer and an interlayer insulating film alternately stacked on each other in which one layer of the impurity doped silicon layers is replaced with a conductive film enabling forming a metal oxide;
forming a mask pattern formed with an opening on the stacked body;
processing the stacked body through the opening to form a hole penetrating the stacked body in a stacking direction;
forming a block insulating film on an inner surface of the hole;
forming a charge trapping layer on a surface of the block insulating film in the hole;
forming a tunnel insulating film on a surface of the charge trapping layer in the hole; and
forming a channel layer on a surface of the tunnel insulating film in the hole.

10. The method for manufacturing a non-volatile semiconductor memory device according to claim 9, wherein the conductive film is etched in forming the hole in the stacked body, and a protective film made of the metal oxide is formed on a side wall of the opening.

11. The method for manufacturing a non-volatile semiconductor memory device according to claim 9, wherein the conductive film is replaced with a topmost impurity doped silicon layer of the stacked body.

12. The method for manufacturing a non-volatile semiconductor memory device according to claim 9, wherein the conductive film is a metal or a metal compound.

13. The method for manufacturing a non-volatile semiconductor memory device according to claim 9, wherein the conductive film is selected from Ti, TiN, Al, and AlN.

14. The method for manufacturing a non-volatile semiconductor memory device according to claim 9, wherein the metal oxide is TiOₓ or AlₓO_{y} (x and y are positive integers).

15. A method for manufacturing a non-volatile semiconductor memory device comprising the steps of:
forming a stacked body having an impurity doped silicon layer and an impurity non-doped silicon layer alternately stacked on each other in which one layer of the impurity doped silicon layers is replaced with a conductive film enabling forming a metal oxide;
forming a mask pattern formed with an opening on the stacked body;
processing the stacked body through the opening to form a hole penetrating the stacked body in a stacking direction;
removing the impurity non-doped silicon layer formed with the hole;
filling an interlayer insulating film in a space from which the impurity non-doped silicon layer is removed;
forming a block insulating film on an inner surface of the hole;
forming a charge trapping layer on a surface of the block insulating film in the hole;
forming a tunnel insulating film on a surface of the charge trapping layer in the hole; and
forming a channel layer on a surface of the tunnel insulating film in the hole.

16. The method for manufacturing a non-volatile semiconductor memory device according to claim 15, wherein the conductive film is etched in forming the hole in the stacked body, and a protective film made of the metal oxide is formed on a side wall of the opening.

17. The method for manufacturing a non-volatile semiconductor memory device according to claim 15, wherein the conductive film is replaced with a topmost impurity doped silicon layer of the stacked body.

18. The method for manufacturing a non-volatile semiconductor memory device according to claim 15, wherein the conductive film is a metal or a metal compound.

19. The method for manufacturing a non-volatile semiconductor memory device according to claim 15, wherein the conductive film is selected from Ti, TiN, Al, and AlN.

20. The method for manufacturing a non-volatile semiconductor memory device according to claim 15, wherein the metal oxide is TiOₓ or AlₓO_{y} (x and y are positive integers).
